(19) United States
(12) Patent Application Publication
(10) Pub. No.: US 2026/0106546 A1
(43) Pub. Date: Apr. 16, 2026

(54) On-Time Determination of a Power Converter

(71) Applicant: TEXAS INSTRUMENTS INCORPORATED, Dallas, TX (US)

(72) Inventors: Manuel Wiersch, Freising (DE); Hermann Eder, Langenpreising (DE); Ricardo Nunes, Freising (DE); Thomas Keller, Attenkirchen (DE)

(21) Appl. No.: 18/912,767

(22) Filed: Oct. 11, 2024

(51) Int. Cl. H02M 3/158; H02M 1/08; H03K 5/00; H03K 5/131; H03K 5/134; H03K 5/135

(52) U.S. Cl. CPC H02M 3/158; H02M 1/08; H03K 5/131; H03K 5/134; H03K 2005/00058; H03K 5/135

(57) ABSTRACT

An apparatus includes a first transistor having a control input and a second transistor having a control input. A first driver has an input. A first output of the first driver couples to the first transistor's control input. A second output of the first driver couples to the second transistor's control input. A third transistor has a control input. A fourth transistor has a control input and couples to the third transistor. A second driver has an input, a first output that couples to the control input of the third transistor, and second output that couples to the control input of the fourth transistor. An adjustable delay circuit has first, second, and third inputs and an output. The first input of the adjustable delay circuit couples to the input of the first driver. The output of the adjustable delay circuit couples to the input of the second driver.

### BACKGROUND

A switching converter has an on-time and an off-time during each switching period. A buck converter is a type of switching converter. During the on-time, magnetic energy is stored in an inductor and delivered to a load. During the on-time, the current through the inductor increases. During the off-time, the input voltage is electrically de-coupled from the inductor and the load, and at least some of the energy previously in the inductor is used to supply current to the load. During the off-time, the inductor's current decreases as the inductor discharges. The duty cycle of a buck is proportional to the ratio of the output voltage to the input voltage. For a relatively small output voltage, the duty cycle of a buck converter may be relatively small thereby resulting in a short on-time. A buck converter may need to implement on-times on the order of 30 nanoseconds (ns) or less to support a combination of small duty cycles and fast switching frequencies.

### SUMMARY

In one example, an apparatus includes a first transistor having a control input and a second transistor having a control input. The second transistor couples to the first transistor at a first switching terminal. A first driver has an input. A first output couples to the control input of the first transistor. A second output couples to the control input of the second transistor. A third transistor has a control input. A fourth transistor has a control input and couples to the third transistor at a second switching terminal. A second driver has an input, a first output couples to the control input of the third transistor, and second output couples to the control input of the fourth transistor. An adjustable delay circuit has first, second, and third inputs and an output. The first input of the adjustable delay circuit couples to the input of the first driver. The output of the adjustable delay circuit couples to the input of the second driver.

In another example, an apparatus includes a first transistor having a control input and a second transistor having a control input. The second transistor is coupled to the first transistor at a switching terminal. A driver has an input, a first output coupled to the control input of the first transistor, and a second output coupled to the control input of the second transistor. An adjustable delay circuit has first, second, and third inputs and an output. The output of the adjustable delay circuit is coupled to the input of the driver. The adjustable delay circuit is configured to generate an output pulse at the output of the adjustable delay circuit based on an input pulse at the first input of the adjustable delay circuit such that: the output pulse has a rising edge delayed from a rising edge of the input pulse by a first delay period, the first delay period based on a first voltage at the second input of the adjustable delay circuit; and the output pulse has a falling edge delayed from a falling edge of the input pulse by a second delay period, the second delay period based on a second voltage at the third input of the adjustable delay circuit.

In yet another example, an apparatus includes an adjustable delay circuit having first, second, and third inputs and an output. The adjustable delay circuit is configured to generate an output pulse at the output based on an input pulse at the first input such that: the output pulse has a rising edge delayed from a rising edge of the input pulse by a first delay period, the first delay period based on a first voltage at the second input of the adjustable delay circuit; and the output pulse has a falling edge delayed from a falling edge of the input pulse by a second delay period, the second delay period based on a second voltage at the third input of the adjustable delay circuit.

### BRIEF DESCRIPTION OF THE DRAWINGS

FIG. 1 a schematic diagram of a test system in which a power converter is coupled to automatic test equipment (ATE), in an example.

FIG. 2 are waveforms of a pulse width modulation (PWM) signal and a delayed PWM signal, in an example.

FIG. 3 is a flowchart illustrating a method for programming time delay values into a replica power stage within the power converter and measuring the minimum on-time of the power converter, in an example.

FIG. 4 is a schematic diagram of a compare circuit within the power converter, in an example.

FIG. 5 is a flowchart illustrating additional detail for programming the time delay values into the replica power stage, in an example.

FIG. 6 includes example waveforms of various signals and voltages illustrating the programming of the turn-off delay of the power converter, in an example.

FIG. 7 is a schematic diagram of an adjustable delay circuit within the power converter, in an example.

FIG. 8 is a timing diagram further illustrating the operation of the adjustable delay circuit, in an example.

FIG. 9 is a schematic diagram of a delay circuit within the adjustable delay circuit, in an example.

FIG. 10 is a flowchart of a method for determining the minimum on-time of the power converter, in an example

FIG. 11 a schematic diagram of a test system in which a power converter is coupled to ATE, in another example.

FIG. 12 is a flowchart of a method for determining the minimum on-time of the power converter, in another example.

### DETAILED DESCRIPTION

The same reference numbers or other reference designators are used in the drawings to designate the same or similar (either by function and/or structure) features.

The examples described herein pertain to a technique and circuitry for determining the minimum on-time for a power converter. A buck converter, which has a high side (HS) transistor coupled in series with a low side (LS) transistor between an input voltage terminal and ground, is described herein as the applicable power converter but the principles may apply to other types of switching power converters. The minimum on-time for a buck converter is the minimum period of time that the HS transistor is on while the buck converter remains in regulation. Regulation means that the buck converter operates in a closed-loop to produce an output voltage at a target level. The described technique includes test equipment to which the buck converter can be coupled. The test equipment electrically interacts with the power converter to determine the minimum on-time for the power converter using a replica power stage which also has HS and LS transistors that are substantially smaller than the main power stage's HS and LS transistors.

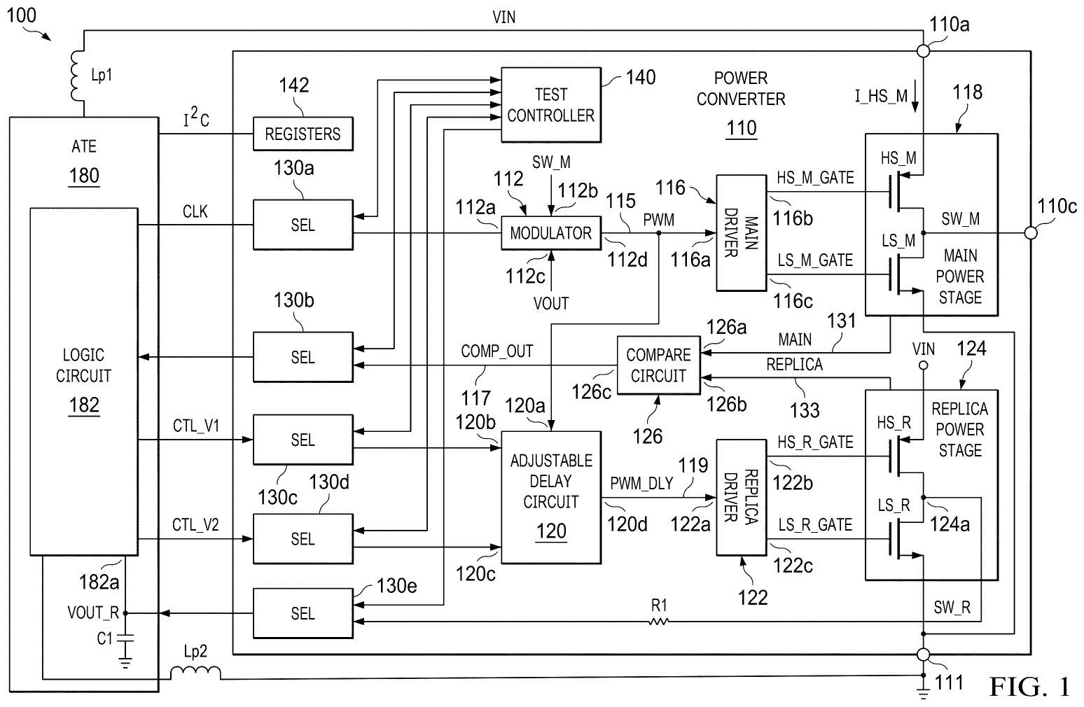

FIG. 1 is a schematic diagram of a test system 100 in which a power converter 110 (e.g., a buck converter) is coupled to automatic test equipment (ATE) 180. As explained below, ATE 180 determines the minimum on-time for the power converter 110. ATE 180 includes a logic circuit 182. Logic circuit 182 may include a programmable processor (e.g., a microprocessor), digital circuitry, etc.

Power converter 110 includes a modulator 112, a main driver 116, a main power stage 118, and adjustable delay circuit 120, a replica driver 122, a replica power stage 124, a compare circuit 126, selection circuits 130a, 130b, 130c, 130d, and 130c (collectively, selection circuits 130), a test controller 140, and registers 142. The switching frequency of the power converter can be programmed via an Inter-Integrated Circuit (I²C) interface into registers 142. The main power stage 118 has a high side main (HS_M) transistor coupled to a low side main (LS_M) transistor between an input voltage terminal 110a and a ground terminal 111. In this example, the HS_M transistor is a p-channel field effect transistor (PFET), and the LS_M transistor is an N-channel field effect transistor (NFET). The drains of the HS_M and LS_M transistors are coupled together and to a main switching terminal 110c. The signal at the main switching terminal 110c is signal SW_M. The main driver 116 has outputs 116b and 116c coupled to the gates of the HS_M and LS_M transistors, respectively. The components of power converter 110 shown in FIG. 1 may be fabricated on an integrated circuit (IC). To generate power to a load, an inductor and output capacitor may be provided on a printed circuit board (PCB) and may be coupled to the main switching terminal 110c. However, during testing in which the ATE 180 determines the minimum on-time of the power converter 110, the inductor and output capacitor may not be included.

The replica power stage 124 has a high side replica (HS_R) transistor coupled to a low side replica (LS_R) transistor between the input voltage terminal 110a and the ground terminal 111. The HS_R transistor is a PFET, and the LS_R transistor is an NFET. The drains of the HS_R and LS_R transistors are coupled together and to a replica switching terminal 124a. The signal at the replica switching terminal 124a is signal SW_R. The replica driver 122 has outputs 122b and 122c coupled to the gates of the HS_R and LS_R transistors, respectively. Replica driver 122 generates gate signals HS_R_GATE and LS_R_GATE to the gates of the HS_R and LS_R transistors.

The HS_M and LS_M transistors are larger than the HS_R and LS_R transistors. The size of a field effect transistor is determined by the ratio of its channel width W to channel length L. In one example, both of the HS_M and LS_M transistors are 1000 times larger than the HS_R and LS_R transistors. Accordingly, for the same terminal voltages (e.g., same gate-to-source voltage (Vgs), same gate-to-drain voltage (Vds), etc.), the drain current through the larger HS_M and LS_M transistors will be larger than through the smaller HS_R and LS_R transistors. In the example in which the HS_R and LS_R transistors are 1000 times smaller than the HS_M and LS_M transistors, the drain current through the HS_R and LS_R transistors will be 1000 times smaller than the drain current through the HS_M and LS_M transistors. Reference to the power stage 118 as being the “main” power stage and to power stage 124 as being the “replica” power stage indicates that the main power stage 118 is used to deliver power to a load, and the replica power stage 124 is not used to deliver power to the load and is substantially smaller than the main power stage 118.

Compare circuit 126 includes an input 126a coupled to main power stage 118 and an input 126b coupled to replica power stage 124. Main power stage 118 provides a signal MAIN 131 to the input 126a. Replica power stage 124 provides a signal REPLICA 133 to input 126b. The signal MAIN 131 indicates whether the HS_M transistor is on. The signal REPLICA 133 indicates whether the HS_R transistor is on. In one example, signal MAIN 131 is the signal SW_M at the main switching terminal 110c and signal REPLICA 133 is the signal SW_R at the replica switching terminal 124a.

Compare circuit 126 has an output 126c through the compare circuit generates an output signal COMP_OUT 117. Compare circuit compares the logic states of signals MAIN and REPLICA 131 and 133 and asserts output signal COMP_OUT 117 to a logic state to indicate whether which of signals MAIN and REPLICA are logic high. For example, compare circuit 126 may assert signal COMP_OUT 117 logic high if signal MAIN 131 is logic high and signal REPLICA 133 is logic low and may assert signal COMP_OUT 117 logic low if signal MAIN 131 is logic low and signal REPLICA 133 is logic high.

Selection circuits 130 include switches (e.g., transistors) that permit more than one use of an external terminal of the IC on which power converter 110 is fabricated. The use of the IC's terminals for testing purposes is illustrated in FIG. 1. For example, a clock signal (CLK) from logic circuit 182 of ATE 180 is provided to selection circuit 130a. Control voltages CTL_V1 and CTL_V2 from logic circuit 182 of ATE 180 are provided to selection circuits 130c and 130d, respectively. Selection circuit 130b is used to provide a comparator output signal COMP_OUT 117 from compare circuit 126 to logic circuit 182 of ATE 180. Selection circuit 130e is used to provide a voltage from replica switching terminal 124a through a resistor R1 to logic circuit 182 of ATE 180. When power converter 110 is not coupled to ATE 180 and is used to deliver power to a load, the signals/voltages through the selection circuits 130 may be different than what is shown in the example of FIG. 1.

Modulator 112 includes inputs 112a, 112b, and 112c and an output 112d. Output 112d of modulator 112 is coupled to input 116a of main driver 116 and to input 120a of adjustable delay circuit 120 and provides a pulse width modulation (PWM) signal 115 to the main driver 116 and to the input 120a of adjustable delay circuit 120. Input 112a of modulator 112 is coupled to the output of selection circuit 130a and accordingly can receive the clock signal CLK from ATE 180. Input 112b of modulator 112 is coupled to the main switching terminal 110c. Input 112c of modulator 112 may be coupled to the connection between resistor R1 and selection circuit 130c, and such connection provides a voltage that is a proxy for the output voltage VOUT. The outputs of selection circuits 130c and 130d are coupled to the respective inputs 120b and 120c of adjustable delay circuit 120. Accordingly, through selection circuits 130c and 130d, ATE 180 may provide control voltages CTL_V1 and CTL_V2 to inputs 120b and 120c of adjustable delay circuit 120. Output 120d of adjustable delay circuit 120 is coupled to the input 122a of replica driver 122. Adjustable delay circuit 120 generates a delayed PWM signal, PWM_DLY, 119 to replica driver 122.

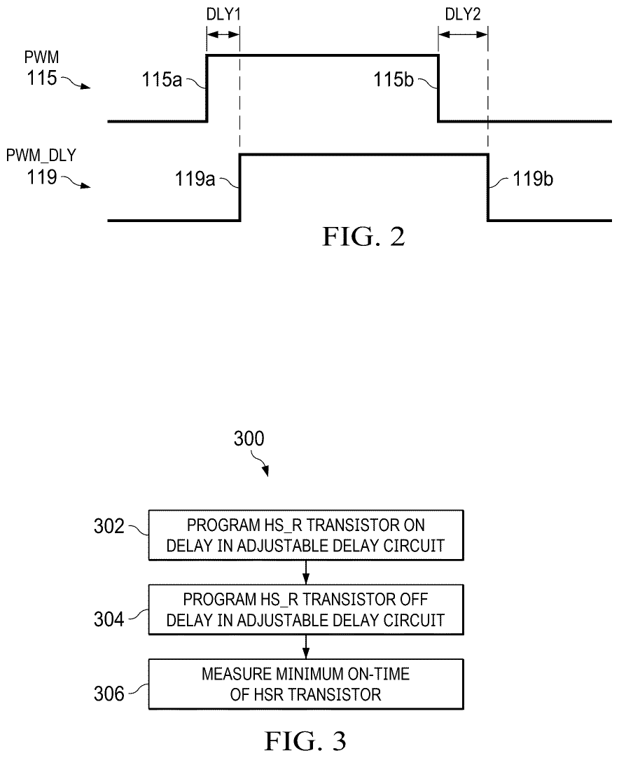

FIG. 2 includes example waveforms for the PWM signal 115 and the PWM_DLY signal 119. In response to rising edge 115a of PWM signal 115, adjustable delay circuit 120 asserts the PWM_DLY signal logic high at rising edge 119a after an ON-delay DLY1 following rising edge 115a. Then, in response to falling edge 115b of PWM signal 115, adjustable delay circuit 120 asserts the PWM_DLY signal logic low at falling edge 119b after an OFF-delay DLY2 following falling edge 115b. The size (e.g., in nanoseconds) of ON-delay DLY1 is independent of the size of OFF-delay DLY2. The ON- and OFF-delays DLY1 and DLY2 may be the same or different. As described below, ON-delay DLY1 is based on the magnitude of control voltage CTL_V1, and OFF-delay DLY2 is based on the magnitude of control voltage CTL_V2.

Referring again to FIG. 1, ATE 180 is configured to determine the minimum on-time for power converter 110. The PWM signal 115 is a cyclical signal having logic highs and logic lows. The PWM signal 115 being logic high represents the on-time of the power converter, and the PWM signal being low represents the off-time of the power converter. During the on-time, in response to the PWM signal 115 being logic high, main driver 116 asserts high side main gate signal (HS_M_GATE) and low side main gate signal (LS_M_GATE) to appropriate logic states to cause the HS_M transistor to be on and the LS_M transistor to be off. During the off-time, in response to the PWM signal 115 being logic low, main driver 116 asserts high side main gate signal (HS_M_GATE) and low side main gate signal (LS_M_GATE) to the opposite logic states to cause the HS_M transistor to be off and the LS_M transistor to be on. As explained above, the minimum on-time is the minimum period of time that the HS_M transistor can be on while the power converter 110 remains in regulation. The minimum on-time for a buck converter corresponds to the lowest allowable duty cycle at the largest allowable switching frequency (fsw). The lowest allowable duty cycle corresponds to the largest permitted input voltage VIN, the smallest output voltage VOUT, and the fastest switching frequency that the power converter can accommodate.

The current through the HS_M and LS_M transistors during each switching cycle can be relatively large, e.g., 50 amperes (A). Accordingly, during each switching cycle, the current I_HS_M through the HS_M transistor may toggle between 0 A and 50 A, and the transition between these two current levels is relatively fast. Accordingly, the rate of change of current I_HS_M through the HS_M transistor is relatively large, e.g., 10 A/ns. The conductors between ATE 180 and power converter 110 carry the input voltage VIN, a ground connection, clock signal CLK, and control voltages CTL_V1 and CTL_V2. The conductors may be part of a single electrical cable or separate wires/cables. Each such conductor has a corresponding parasitic inductance. FIG. 1 includes a parasitic inductance Lp1 for the input voltage VIN conductor and a parasitic inductance Lp2 for the ground connection. The voltage drop across an inductor is proportional to the product of the parasitic inductance and the rate of change of current with respect to time (e.g., Lp1*di/dt). The voltage drop across parasitic inductances Lp1 and Lp2 can be substantial due to the relative large di/dt values associated with the main power stage 118. Such parasitic voltage drops can cause supply and ground noise and high voltage spikes. Thereby potentially triggering under-voltage lockout states, disturbing the regulation of the output voltage, or triggering of other failure modes.

As described below, the replica power stage 124 is used to measure the minimum on-time of power converter 110. Because the HS_R and LS_R transistors of the replica power stage 124 are smaller than the HS_M and LS_M transistors of the remain power stage 118, the current through the HS_R and LS_R transistors of the replica power stage is smaller as well. Accordingly, the value of di/dt through the replica power stage transistors is smaller which advantageously results in smaller voltage drop across the parasitic inductances Lp1 and Lp2 when using the replica power stage to measure the minimum on-time of power converter 110.

As described below, the replica power stage 124 is also used to determine the minimum on-time of the HS_M transistor. The minimum on-time determination process includes two steps. First, the adjustable delay circuit 120 is programmed such that the turn-on and turn-off times of the HS_R and LS_R transistors in response to the PWM signal 115 approximates the corresponding turn-on and turn-off times of the HS_M and LS_M transistors. The turn-on time of the HS_M transistor is the elapsed time period between a rising edge 115a of the PWM signal 115 and when the HS_M transistor turns on. The turn-off time of the HS_M transistor is the elapsed time period between a falling edge 115b of the PWM signal 115 and when the HS_M transistor turns off. Second, the replica power stage 124 is then used to determine the minimum on-time of the HS_R transistor. With the turn-on and turn-off times of the replica power stage 124 approximately matching that of the main power stage 118, the minimum on-time of the HS_R transistor will approximate that of the HS_M transistor.

The reason for the first step in causing the turn-on and turn-off times of the HS_R and LS_R transistors to approximate those of the HS_M and LS_M transistors is as follows. A rising edge of the PWM signal 115 should turn on the HS_M transistor and turn off the LS_M transistor, and a falling edge of the PWM signal should turn off the HS_M transistor and turn on the LS_M transistor. However, there is a delay between the rising edge of the PWM signal 115 and when the HS_M transistor turns on. For example, main driver 116 introduces some time delay between receipt of the PWM signal 115 and the main driver 116 asserting the HS_M_GATE signal to a logic state to turn on HS_M transistor. Similarly, the main driver 116 introduces a delay in responding to a falling edge of the PWM signal 115 to turn off the HS_M transistor. Further, the gate capacitance of the HS_M and LS_M transistors introduces additional delay for turning on the HS_M and LS_M transistors. Accordingly, as noted above, the first step in the determination of the minimum on-time of the power converter 110 is to program the adjustable delay circuit 120 to introduce separate time delays for turning on and off the HS_R transistor so as to approximately match the delays associated with turning on and off the HS_M and LS_M transistors.

FIG. 3 is a flow chart 300 illustrating an example method for determining the minimum on-time of power converter 110. The method illustrated in FIG. 3 is initiated upon the power converter 110 being placed into a test mode. In an example, logic circuit 182 within ATE 180 toggles the signal lines to one or more of selection circuits 130 with predetermined bit patterns and/or voltage waveforms that would not normally occur during normal operation. Test controller 140 detects the occurrence of the predetermined bit patterns and/or waveforms and transitions into the test mode. During the test mode, test controller 140 operates the state of the selection circuits 130 to cause the signaling described herein and shown in FIG. 1 to occur. For example, selection circuits 130c and 130d are configured to allow control voltages CTL_V1 and CTL_V2 to pass through from ATE 180 to inputs 120b and 120c of adjustable delay circuit 120.

At operation 302, the method includes programming the adjustable delay circuit 120 for the HS_R transistor's ON delay. Following a rising edge 115a of the PWM signal 115, replica driver 122 introduces a delay before assertion of the gate signal HS_R_GATE to the gate of the HS_R transistor. Further, upon assertion of the gate signal HS_R_GATE, the gate capacitance of the HS_R transistor takes a finite amount of time to charge. The combination of these delays and any other delays in the replica power stage signal chain may be different than the turn-on delay of the HS_M transistor. Similarly, the turn-off delay of the HS_R transistor may be different than the turn-off delay of the HS_M transistor. The ON delay for the HS_R transistor is a time period implemented by adjustable delay circuit 120 that, when added to any other delays noted above caused by the replica driver 122, etc., causes the turn-on time for the HS_R transistor to be approximately the same as the turn-on time for the HS_M transistor. Adjustable delay circuit 120 implements the ON delay for the HS_R transistor based on control voltage CTL_V1.

At operation 304, the method includes programming the adjustable delay circuit 120 for the HS_R transistor's OFF delay. The HS_R transistor's OFF delay is a time period implemented by adjustable delay circuit 120 that, when added to any other delays noted above caused by the replica driver 122, etc., causes the turn-off time for the HS_R transistor to be approximately the same as the turn-off time for the HS_M transistor. Adjustable delay circuit 120 implements the OFF delay for the HS_R transistor based on control voltage CTL_V2.

At operation 306, the method includes measuring the minimum on-time of the HS_R transistor. Because the turn-on and turn-off delays for transistor HS_R have been set to approximate the turn-on and turn-off delays for transistor HS_M, the minimum on-time for transistor HS_R will approximate the minimum on-time for transistor HS_M. Multiple techniques are described below for measuring the minimum on-time for transistor HS_R.

As noted above, compare circuit 126 determines which of signals MAIN and REPLICA are logic high. The output signal COMP_OUT 117 from compare circuit 126 is provided through selection circuit 130b to logic circuit 182 of ATE 180. As described below, logic circuit 182 uses the compare circuit's output signal COMP_OUT 117 to determine voltage levels for the control voltages CTL_V1 and CTL_V2.

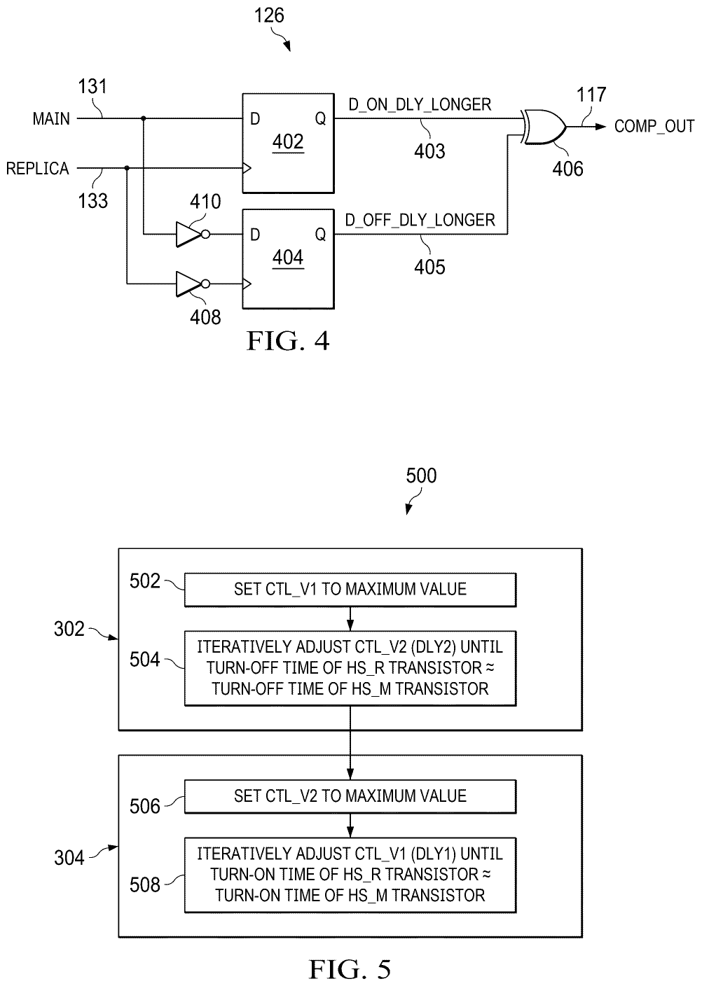

FIG. 4 is a schematic diagram of compare circuit 126, in an example. In this example, compare circuit 126 includes flip-flops (e.g., D flip-flops) 402 and 404, an exclusive OR gate 406, and inverters 408 and 410. Each flip-flop 402 and 404 has a data (D) input, a clock input, and a Q output. Signal MAIN from main power stage 118 is provided to the D input of flip-flop 402 and, through inverter 410, to the D input of flip-flop 404. Signal REPLICA from replica power stage 124 is provided to the clock input of flip-flop 402 and, through inverter 408, to the clock input of flip-flop 404. The signal at the Q output of flip-flop 402 is signal D_ON_DLY_LONGER 403. The signal at the Q output of flip-flop 404 is signal D_OFF_DLY_LONGER 405 The Q outputs of flip-flops 402 and 404 are coupled to inputs of exclusive-OR gate 406. Exclusive-OR gate 406 exclusively ORs signals D_ON_DLY_LONGER 403 and D_OFF_DLY_LONGER 405 to generate signal COMP_OUT 117 at its output.

Because signal REPLICA 133 is the clock signal for flip-flop 402 and signal MAIN 131 is provided to the D input of flip-flop 402, when an edge (e.g., a rising edge) of signal REPLICA 133 occurs to clock flip-flop 402, the signal D_ON_DLY_LONGER 403 will be asserted to the same logic state as signal MAIN 131. Accordingly, if signal MAIN 131 is logic high when signal REPLICA 133 has a rising edge, then signal D_ON_DLY_LONGER 403 will be asserted to a logic high state which indicates that signal MAIN 131 was asserted to a logic high state by main power stage 118 before replica power stage 124 asserted signal REPLICA 133 to a logic high state. This means that transistor HS_M turned on before transistor HS_R turned on in response to a rising edge 115a of the PWM signal 115. By contrast, a logic low assertion of signal D_ON_DLY_LONGER 403 indicates that transistor HS_R turned on before transistor HS_M in response to a rising edge 115a of the PWM signal 115.

Because the logical inverse of signal REPLICA 133 is the clock signal for flip-flop 404 and the logical inverse signal MAIN 131 is provided to the D input of flip-flop 404, when a falling edge of signal REPLICA 133 occurs, the signal D_OFF_DLY_LONGER 405 will be asserted to the same logic state as the logical inverse signal MAIN 131. Accordingly, flip-flop 404 assets signal D_OFF_DLY_LONGER 405 to a logic state indicative of which of the falling edges of signals MAIN and REPLICA occurred before the other. For example, if the falling edge 115b of signal MAIN 131 occurs before the falling edge 119b of signal REPLICA, flip-flop 404 asserts signal D_OFF_DLY_LONGER 405 to a logic high state. Conversely, if the falling edge 115b of signal MAIN 131 occurs after the falling edge 119b of signal REPLICA, flip-flop 404 asserts signal D_OFF_DLY_LONGER 405 to a logic high low.

FIG. 5 is a flowchart 500 further illustrating operations 302 and 304 of FIG. 2. In the example of FIG. 5, operation 302 includes operations 502 and 504. Operation 502 includes setting the control voltage CTL_V1 to a maximum value. In one example, logic circuit 182 of ATE 180 sets the control voltage CTL_V1 to its maximum value. In one example, adjustable delay circuit 120 implements larger ON-delays DLY1 in response to larger control voltages CTL_V1. The largest setting for the control voltage CTL_V1 results in an ON-delay DLY1 for the HS_R transistor that causes the HS_R transistor turn on at a point in time assured to be after the HS_M transistor turns on. In other examples, the value of control voltage CTL_V1 set in operation 502 is any voltage that causes the ON-delay DLY1 to be sufficiently large to assure that the HS_R transistor turns on after the HS_M transistor.

Referring back to FIG. 4, by forcing the HS_R transistor to turn on before the HS_M transistor, a rising edge of signal MAIN 131 will occur after the rising edge of signal REPLICA 133 following a rising edge 115a of a PWM signal 115. Accordingly, signal D_ON_DLY_LONGER 403 will be a logic low (“0”), and the output signal COMP_OUT 117 from exclusive-OR gate 406 will have the same logic state as signal D_OFF_DLY_LONGER 405. Flip-flop 404 will force signal D_OFF_DLY_LONGER 405 to be logic low if signal MAIN 131 is logic high when the subsequent falling edge of signal REPLICA 133 occurs. Conversely, flip-flop 404 will force signal D_OFF_DLY_LONGER 405 to be logic high if signal MAIN 131 is logic low when the subsequent falling edge of signal REPLICA 133 occurs. Accordingly, with the ON-delay DLY1 set to a sufficiently large value (e.g., its maximum value) to ensure that the HS_M transistor turns on before the HS_R turns on in response to a rising edge 115a of the PWM signal, the logic state of signal COMP_OUT indicates whether transistor HS_R turned off before or after transistor HS_M turned off in response to a falling edge 115a of the PWM signal 115.

Operation 504 includes iteratively adjusting the control voltage CTL_V2, which causes adjustable delay circuit 120 to adjust the OFF-delay DLY2, until the turn-off time of the HS_R transistor is approximately equal to the turn-off time of the HS_M transistor. In one example, logic circuit 182 monitors the state of signal COMP_OUT and adjusts the control voltage CTL_V2 to shorten or length the OFF-delay DLY2 until the logic state of signal COMP_OUT changes state. For example, logic circuit 182 increases the control voltage CTL_V2 if COMP_OUT is logic low and decreases the control voltage CTL_V2 if COMP_OUT is logic high. In another example, the logic circuit 182 makes a predetermined number (e.g., four) of adjustments to control voltage CTL_V2 based on the logic state of signal COMP_OUT.

After the control voltage CTL_V2 is set, which sets the OFF-delay DLY2 to a value such that the turn-off time of the HS_R transistor is approximately the same as the turn-off time of the HS_M transistor, operations 506 and 508 are performed. Operations 506 and 508 are largely the same as operations 502 and 504 adjustments to the turn-time is made.

Operation 506 includes setting the control voltage CTL_V2 to a maximum value, or any voltage that assures that the HS_R transistor turns off before the HS_M transistor turns off. By forcing the HS_R transistor to turn off before the HS_M transistor, a falling edge of signal MAIN 131 will occur after the corresponding falling edge of signal REPLICA 133 Accordingly, signal D_OFF_DLY_LONGER 405 will be a logic low, and the output signal COMP_OUT 117 from exclusive-OR gate 406 will have the same logic state as signal D_ON_DLY_LONGER 403. Flip-flop 402 will force signal D_ON_DLY_LONGER 403 to be logic low if signal MAIN 131 is logic low when a rising edge of signal REPLICA 133 occurs. Conversely, flip-flop 402 will force signal D_ON_DLY_LONGER 403 to be logic high if signal MAIN 131 is logic high when a rising edge of signal REPLICA 133 occurs. Accordingly, with the OFF-delay DLY2 set to a sufficiently large value (e.g., its maximum value) to ensure that the HS_M transistor turns off before the HS_R turns off, the logic state of signal COMP_OUT 117 indicates whether transistor HS_R turned on before or after transistor HS_M turned on.

Operation 508 includes iteratively adjusting the control voltage CTL_V1, which causes adjustable delay circuit 120 to adjust the ON-delay DLY1, until the turn-on time of the HS_R transistor is approximately equal to the turn-on time of the HS_M transistor. As described above, logic circuit 182 may monitor the state of signal COMP_OUT 117 and adjust the control voltage CTL_V1 to shorten or length the ON-delay DLY1 until the logic state of signal COMP_OUT changes state. In one example, logic circuit 182 increases the control voltage CTL_V1 if signal COMP_OUT 117 is logic high and decreases the control voltage CTL_V1 if signal COMP_OUT is logic low. In another example, the logic circuit 182 makes a predetermined number (e.g., four) of adjustments to control voltage CTL_V1 based on the logic state of signal COMP_OUT 117.

The use of flip-flops 402 and 404 and exclusive-OR gate 406 allows information regarding both the turn-on and turn-off times of the HS_R transistor relative to the HS_M transistor to be communicated via a single signal, COMP_OUT 117, to ATE 180. In another example, rather than using an exclusive-OR gate, signals D_ON_DLY_LONGER 403 and D_OFF_DLY_LONGER 405 are communicated separately to ATE 180. In this latter example, the sequential process of forcing a maximum value for one the ON-time delay DLY1 (or OFF-time delay DLY2) and monitoring the turn-off delay (turn-on delay) is not performed. Instead, logic circuit 182 adjusts the control voltages CTL_V1 and CTL_V2 simultaneously based on the logic states of the D_ON_DLY_LONGER signal 403 and D_OFF_DLY_LONGER signal 405.

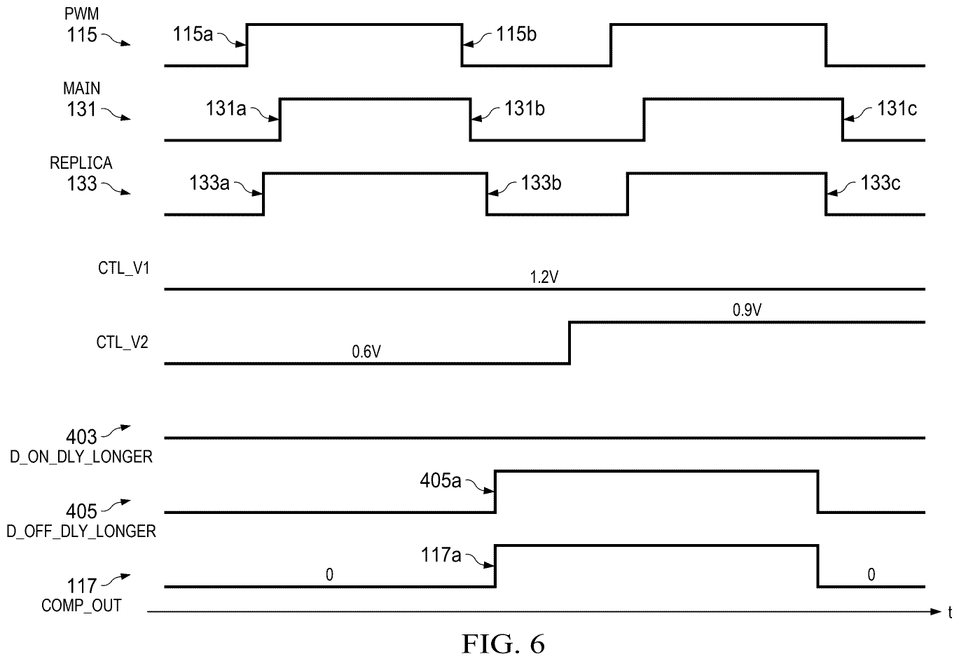

FIG. 6 includes example waveforms of various signals and voltages illustrating the programming of the turn-off delay for the HS_R transistor, which corresponds to operations 502 and 504 of FIG. 5. FIG. 6 includes example waveforms the PWM signal 115, signals MAIN 131 and REPLICA 133, the control voltages CTL_V1 and CTL_V2, and signals D_ON_DLY_LONGER 403, D_OFF_DLY_LONGER 405, and COMP_OUT 117. In one example, the control voltages CTL_V1 and CTL_V2 range from 0V to 1.2V. A voltage of 0V corresponds to the largest amount of delay, and a voltage of 1.2V corresponds to the smallest amount of delay. In the example of FIG. 6, the control voltage CTL_V1 is set at a level of 1.2V corresponding to the smallest ON-delay DLY1 for the HS_R transistor, corresponding to operation 502 in FIG. 5.

Control voltage CTL_V2 may be initialized to a mid-range value of 0.6V, which is the case in the example of FIG. 6. In response to the rising edge 115a of the PWM signal 115, because the control voltage CTL_V1 is set at 1.2V (its maximum value), the HS_R transistor turns on, as indicated by rising edge 133a of the signal REPLICA 133, before the HS_M transistor, as indicated by rising edge 131a of the MAIN signal 131. Accordingly, signal D_ON_DLY_LONGER 403 is logic low. With control voltage CTL_V2 set at 0.6V, in response to falling edge 115b of the PWM signal 115, the HS_R transistor turns off (falling edge 133b of signal MAIN 131) after the HS_M transistor turns off (falling edge 131b of signal REPLICA 133). In response to the signal MAIN 131 being logic low when the falling edge 133b of the signal REPLICA occurs, signal D_OFF_DLY_LONGER 405 becomes logic high as indicated at rising edge 405a. With signal D_ON_DLY_LONGER 403 being logic low and signal D_OFF_DLY_LONGER 405 being logic high, signal COMP_OUT 117 from exclusive-OR gate 406 becomes logic high as indicated at rising edge 117a.

Logic circuit 182 responds to a logic high assertion of signal COMP_OUT 117 by increasing the control voltage CTL_V2 by an incremental amount (e.g., 0.3V) from 0.6V to 0.9V. In response to the increase in control voltage CTL_V2, the OFF-delay DLY2 is decreased by adjustable delay circuit 120. FIG. 6 illustrates that, in response to the next falling edge 115c of the PWM signal 115, the HS_R transistor turns off (falling edge 133c of signal REPLICA 133) before the HS_M transistor turns off (falling edge 131c of signal MAIN 131). The signal COMP_OUT 117 is forced low at falling edge 117b by the exclusive-OR gate 406 because signals D_ON_DLY_LONGER 403 and D_OFF_DLY_LONGER 405 are both logic low upon falling edge 133c of the signal REPLICA 133. This iterative process continues as described above.

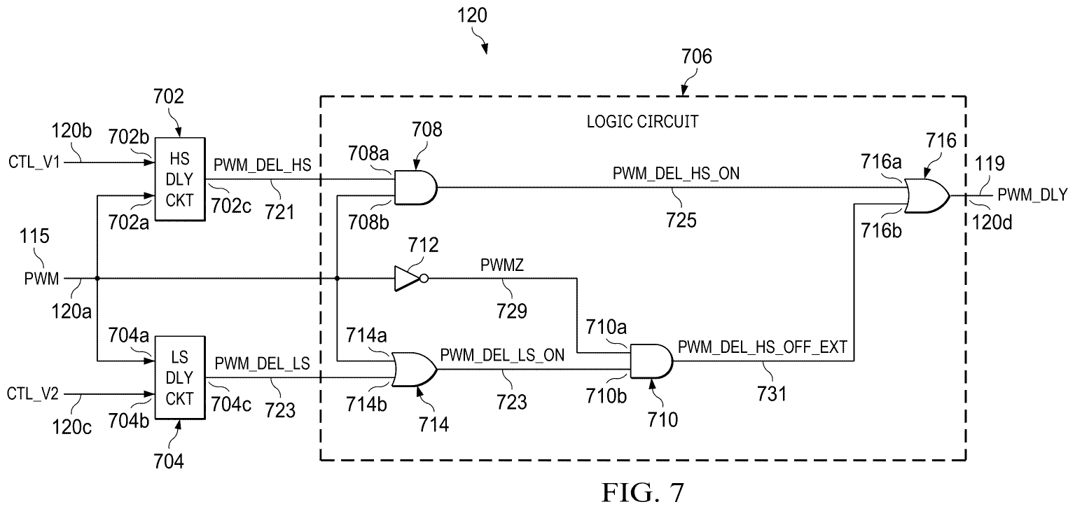

FIG. 7 is a schematic diagram of adjustable delay circuit 120, in an example. Adjustable delay circuit 120 includes a high side delay circuit 702, a low side delay circuit 704, and a logic circuit 706. In this example, logic circuit 706 includes AND gates 708 and 710, an inverter 712, and OR gates 714, and 716. High side delay circuit 702 has inputs 702a and 702b, and an output 702c. Similarly, low side delay circuit 704 has inputs 704a and 704b, and an output 704c. Inputs 702a and 704a are coupled to input 120a of adjustable delay circuit 120. Input 702b of high side delay circuit 702 is coupled to input 120b of adjustable delay circuit 120. Input 704b of low side delay circuit 704 is coupled to input 120c of adjustable delay circuit 120.

AND gate 708 has inputs 708a and 708b. OR gate 714 has inputs 714a and 714b. Inputs 708b and 714a of AND gate 708 and OR gate 714, respectively, and an input of inverter 712 are coupled to input 120a of adjustable delay circuit 120. The output 702c of high side delay circuit 702 is coupled to the input 708a of AND gate 708. The output 704c of low side delay circuit 704 is coupled to the input 714b of OR gate 714. The output of inverter 712 is coupled to the input 710a of AND gate 710. The output of OR gate 714 is coupled to the input 710b of AND gate 710. The output of AND gates 708 and 710 are coupled to respective inputs 716a and 716b of OR gate 716. The output of OR gate 716 is coupled to the output 120d of adjustable delay circuit 120.

PWM signal 115 is provided to the input 702a of high side delay circuit 702, the input 704a of low side delay circuit 704, the input 708b of AND gate 708, the input of inverter 712, and the input 714a of OR gate 714. The control voltage CTL_V1 is provided to the input 702b of high side delay circuit 702. The output signal from high side delay circuit 702 is called the PWM_DEL_HS signal 721. High side delay circuit 702 delays the PWM signal 115 by a time period based on the magnitude of control voltage CTL_V1. Accordingly, the PWM_DEL_HS signal 721 is a delayed version of the PWM signal 115—the length of the time delay being based on the control voltage CTL_V1. The output signal from low side delay circuit 704 is called the PWM_DEL_LS signal 723. Low side delay circuit 704 delays the PWM signal 115 by a time period based on the magnitude of control voltage CTL_V2. Accordingly, the PWM_DEL_LS signal 723 is a delayed version of the PWM signal 115—the length of the time delay being based on the control voltage CTL_V2.

AND gate 708 logically ANDs the PWM_DEL_HS signal 721 and the PWM signal 115 to produce PWM_DEL_HS_ON signal 725. Inverter 712 logically inverts the PWM signal 115 as PWMZ signal 729. OR gate 714 logically ORs the PWM signal 715 and the PWM_DEL_LS signal 723 to produce PWM_DEL_LS_ON signal 727. AND gate 710 logically ANDs the PWMZ signal 729 and the PWM_DEL_LS_ON signal 727 as PWM_DEL_HS_OFF_EXT signal 731. OR gate 716 logically ORs the PWM_DEL_HS_ON SIGNAL 725 and the PWM_DEL_HS_OFF_EXT signal 731 as the PWM_DLY signal 119.

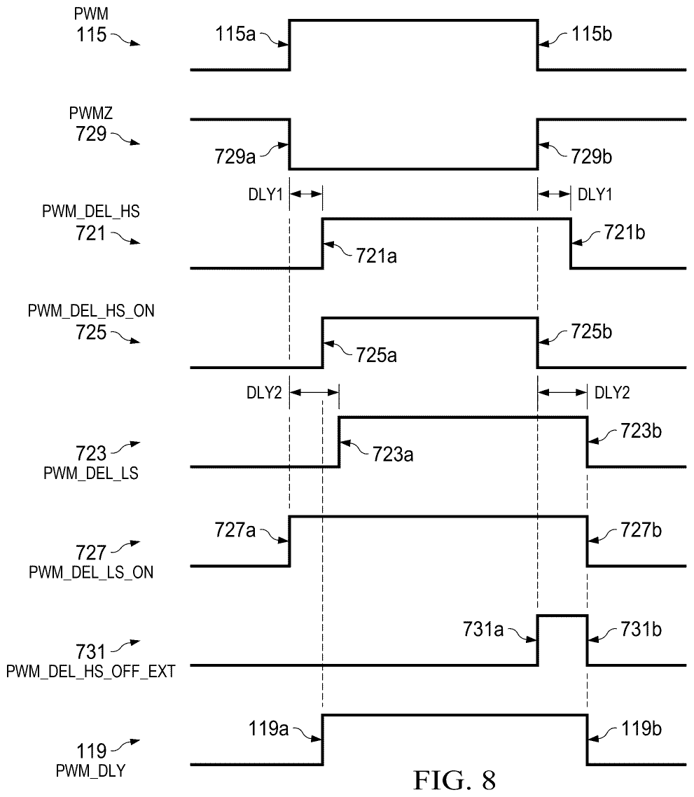

FIG. 8 is a timing diagram further illustrating the operation of adjustable delay circuit 120 in the example of FIG. 7. The signals in FIG. 8 include the PWM signal 115, the PWMZ signal 729, the PWM_DEL_HS signal 721, the PWM_DEL_HS_ON signal 725, the PWM_DEL_LS signal 723, the PWM_DEL_LS_ON signal 727, the PWM_DEL_HS_OFF_EXT signal 731, and the PWM_DLY signal 119. The PWM signal 115 has rising and falling edges 115a and 115b, respectively. PWMZ 729 is the logical inverse of the PWM signal 115 and has corresponding falling and rising edges 729a and 729b. Based on the magnitude of the control voltage CTL_V1, the PWM_DEL_HS signal 721 is delayed from the PWM signal 115 by ON-delay DLY1 and has rising and falling edges 721a and 721b, respectively. Signal DEL_DEL_HS_ON 725 is the logical AND of the PWM_DEL_HS signal 721 and the PWM signal 115 and, accordingly, has a rising edge 725a commensurate with the rising edge 721a of the PWM_DEL_HS signal 721 and a falling edge 725b commensurate with the falling edge 115b of the PWM signal 115.

Based on the magnitude of the control voltage CTL_V2, the PWM_DEL_LS signal 723 is delayed from the PWM signal 115 by OFF-delay DLY2 and has rising and falling edges 723a and 723b, respectively. Signal DEL_DEL_LS_ON 727 is the logical OR of the PWM_DEL_LS signal 723 and the PWM signal 115 and, accordingly, has a rising edge 727a commensurate with the rising edge 115a of the PWM signal 115 and a falling edge 727b commensurate with the falling edge 723b of the PWM_DEL_LS signal 723.

Signal PWM_DEL_HS_OFF_EXT 731 is the logical AND of the PWMZ signal 729 and the PWM_DEL_LS_ON signal 727 and has a rising edge 731a commensurate with the rising edge 729b of the PWMZ signal 729 and a falling edge 731b commensurate with the falling edge 727b of the PWM_DEL_LS_ON signal 727. Finally, the PWM_DLY signal 119 is the logical OR of the PWM_DEL_HS_ON signal 725 and the PW_DEL_LS_OFF_EXT signal and has a rising edge 119a commensurate with the rising edge 725a of the PWM_DEL_HS_ON signal 725 and a falling edge 119b commensurate with the falling edge 731b of the PWM_DEL_HS_OFF_EXT signal 731. Accordingly, the rising edge 119a of the PWM_DLY signal 119 is delayed from the rising edge 115a of the PWM signal 115 by the ON-delay DLY1 and the falling edge 119b of the PWM_DLY signal 119 is delayed from the falling edge 115b of the PWM signal 115 by the OFF-delay DLY2.

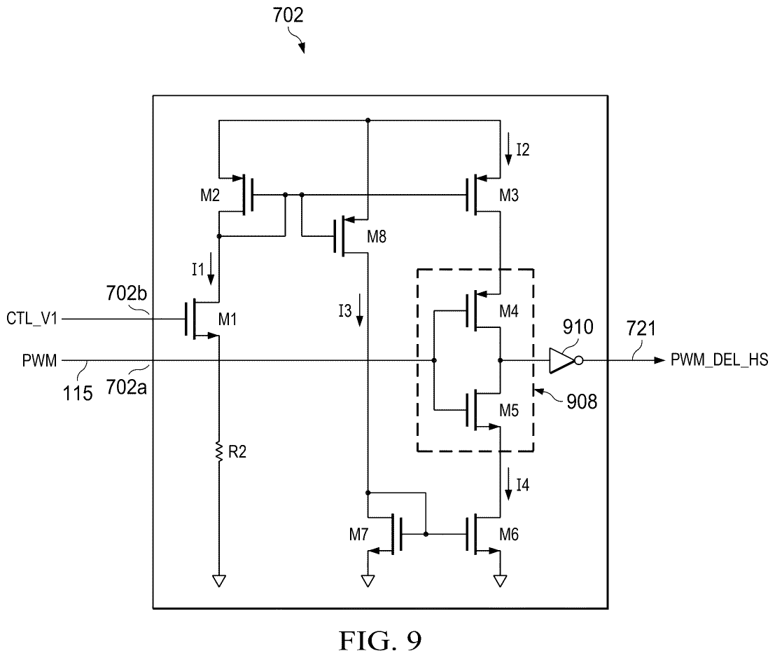

FIG. 9 is a schematic diagram of the high side delay circuit 702. The low side delay circuit 704 may be implemented the same. High side delay circuit 702 includes transistors M1, M2, M3, M4, M5, M6, M7, and M8, resistor R2, and an inverter 910. In this example, transistors M1 and M5-M7 are NFETs and transistors M2-M4 and M8 are PFETs. Transistors M2 and M3 are coupled together to form a current mirror, and transistors M2 and M8 are coupled together to form a current mirror. Similarly, transistors M7 and M6 are coupled together to form a current mirror. The drains of transistors M4 and M5 are coupled together and to an input of inverter 910. The gates of transistors M4 and M5 are coupled together and to input 702a and receives the PWM signal 115. Transistors M4 and M5 form an inverter 908. The drains of transistors M1 and M2 are coupled together. Resistor R2 is coupled between the source of transistor M1 and ground. The gate of transistor M1 is coupled to input 702b and receives the control voltage CTL_V1.

The magnitude of control voltage CTL_V1 sets the current I1 through transistor M1. Current I1 is mirrored as current I2 through transistor M3 and current I3 through transistor M8. Current I3 is then mirrored as current I4 through transistor M4. Currents I2 and I4 are approximately equal and form the bias current through inverter 908 formed by transistors M4 and M5. Inverter 908 logically inverts the PWM signal 115 with switching speeds of transistors M4 and M5 which are based on the bias current I2 and I4. For example, with a lower level of currents I2 and I4, the response time of inverter 908 is slower than would be the case at a higher level of currents I2 and I4. Accordingly, the magnitude of currents I2 and I4 sets the time delay implemented by high side delay circuit 702. Inverter 910 is included to invert the output signal from inverter 908 (at the drains of transistors M4 and M5) back to the same logic level as the original signal, PWM signal 115.

With the turn-on and turn-off times of the HS_R and LS_R transistors being approximately equal to the corresponding turn-on and turn-off times of the HS_M and LS_M transistors, the minimum on-time of the HS_R transistor is approximately equal to the minimum on-time of the HS_M transistor. Accordingly, the replica power stage 124 can be used to measure the minimum-on time of the HS_R transistor. Referring back to FIG. 1, ATE 180 includes a capacitor C1 coupled between a terminal 182a of logic circuit 182 and ground. Resistor R1 within power converter 110 is coupled between the replica switching terminal 124 and terminal 182a of logic circuit 182. The voltage across capacitor C1 is VOUT_R, which is a proxy for the output voltage of power converter 110 if the additional components (e.g., an inductor and an output capacitor) were coupled to the main switching terminal 110c. Modulator 112 generates the PWM signal 115 based on, for example, an clock signal CLK from ATE 180, the output voltage VOUT, and the voltage SW_M at the main switching terminal 110c.

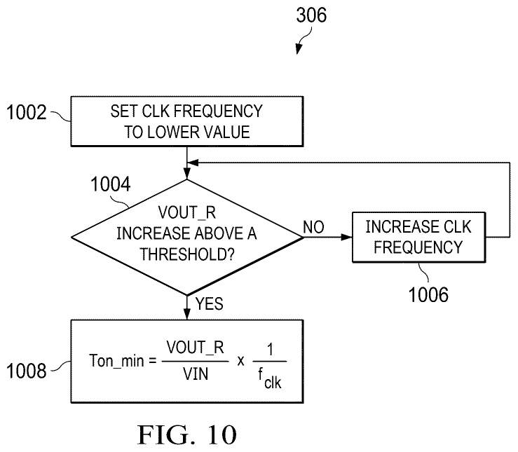

FIG. 10 is a flowchart illustrating one technique for determining the minimum on-time of the HS_R transistor. At operation 1002, logic circuit 182 of ATE 180 sets the frequency of clock signal CLK to a low value, for example, a frequency low enough that power converter 110 assuredly can remain in regulation. At 1004, logic circuit 182 determines whether voltage VOUT_R has increased above a threshold. If the frequency of clock signal CLK is low enough that the on-time of the HS_R transistor is larger than its minimum on-time, power converter 110 remains in regulation and voltage VOUT_R is within a threshold level of its regulated level.

If logic circuit 182 determines that voltage VOUT_R is within a threshold level of its regulated level, then at operation 1006, logic circuit 182 increases the frequency of clock signal CLK, and control loops back to decision operation 1004. This process continues until logic circuit 182 determines that voltage VOUT_R has risen above the threshold level. This will occur because to maintain voltage VOUT_R at its regulated level for the specified frequency of clock signal CLK and the PWM signal 115, the on-time of the HS_R transistor would have to be less than the minimum on-time. The on-time of the HS_R transistor cannot decrease below its minimum on-time. When this happens, the on-time of the HS_R transistor is too long for voltage VOUT_R to remain at its regulated level and, accordingly, voltage VOUT_R increases above the threshold level.

At operation 1008, logic circuit 182 determines the minimum on-time for the HS_R transistor (Ton_min), which also is the minimum on-time for the HS_M transistor as:

$$Ton\_min = \frac{VOUT\_R}{VIN} * \frac{1}{{f}_{clk}} \qquad ( Eq . 1 )$$

where f_{clk} is the frequency of the clock signal CLK at which logic circuit 182 determined that voltage VOUT_R increased above the threshold level.

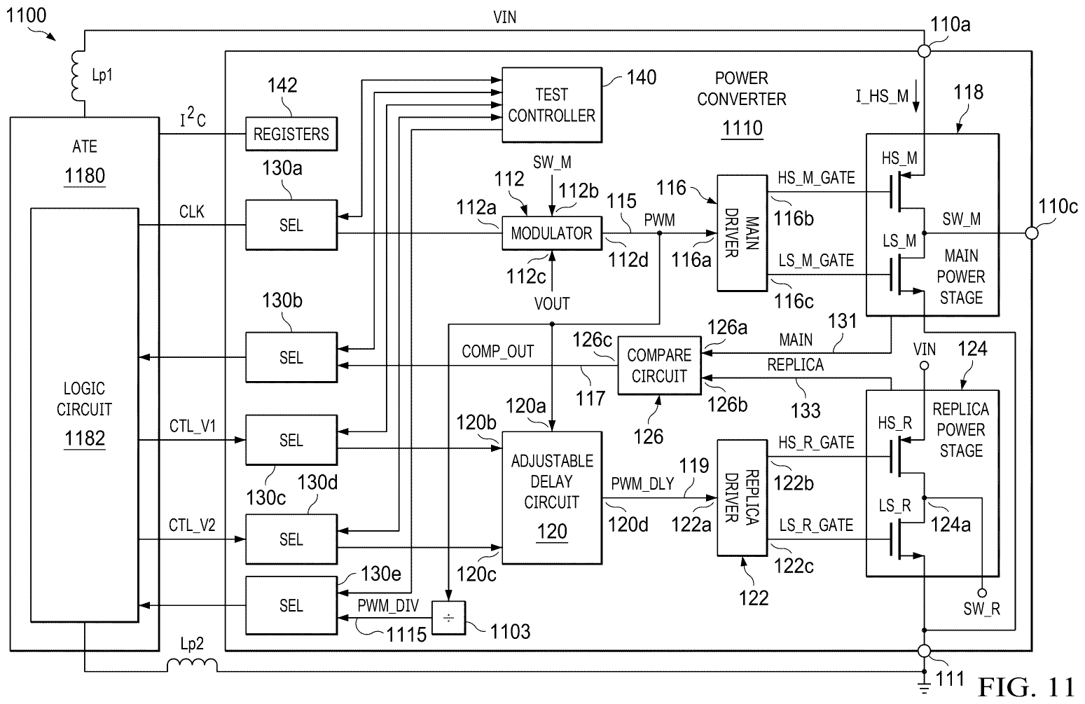

FIG. 11 is a schematic diagram of a test system 1100 in which a power converter 1110 (e.g., a buck converter) is coupled to automatic test equipment (ATE) 1180, which includes logic circuit 1182. The components and their configuration of power converter 1110 and ATE 1180 are largely the same as that shown in FIG. 1 and described above. A difference is that power converter 1110 includes a frequency divider 1103, which receives the PWM signal 115 as an input and generates an output signal PWM_DIV 1115 as an output signal. Signal PWM_DIV 1115 has a lower frequency than the PWM signal 115 based on a divide ratio implemented by frequency divider 1103. Logic circuit 1182 receives the PWM_DIV signal 1115 and determines the frequency of the PWM_DIV signal. Logic circuit 1182 can determine the frequency of the PWM signal 115 based on the frequency of the PWM_DIV signal 1115 and the divide ratio of the frequency divider 1103. In another example, frequency divider 1103 is not included and the PWM signal 115 is provided to logic circuit 1182.

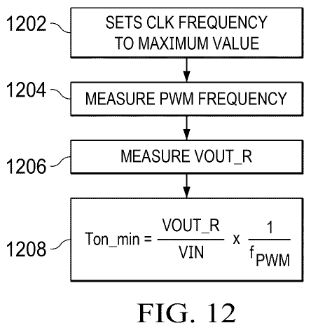

FIG. 12 is a flowchart illustrating one technique for determining the minimum on-time of the HS_R transistor. At operation 1102, logic circuit 1182 of ATE 1180 sets the frequency of clock signal CLK to a value high enough for which power converter 1110 is unable to maintain regulation. In one example, logic circuit 1182 sets the frequency of clock signal CLK at a maximum value. At operation 1204, logic circuit 1182 measures the frequency of the PWM signal 115. In one example, logic circuit 1182 measures the frequency of the PWM_DIV signal 1115 and, based on the divide ratio of frequency divider 1103, calculates the frequency of the PWM signal 115. At the highest frequency of the clock signal CLK, the frequency of the PWM signal 115 will be less than the frequency set for the clock signal CLK because modulator 112 will maintain regulation for the power converter 1110 based on a maximum possible frequency for the PWM signal 115, which less than the frequency set by logic circuit 1182 for the clock frequency CLK. At operation 1206, logic circuit 1182 measures the magnitude of voltage VOUT_R. At operation 1208, logic circuit 1182 determines the minimum on-time for the HS_R transistor, Ton_min, which also is the minimum on-time for the HS_M transistor as:

$$Ton\_min = \frac{VOUT\_R}{VIN} * \frac{1}{{f}_{PWM}} \qquad ( Eq . 2 )$$

where f_{PWM} is the frequency of the PWM signal 115 determined at operation 1204.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. An apparatus, comprising:
a first transistor having a control input;
a second transistor having a control input, the second transistor coupled to the first transistor at a first switching terminal;
a first driver having an input, a first output coupled to the control input of the first transistor, and second output coupled to the control input of the second transistor;
a third transistor having a control input;
a fourth transistor having a control input, the fourth transistor coupled to the third transistor at a second switching terminal;
a second driver having an input, a first output coupled to the control input of the third transistor, and second output coupled to the control input of the fourth transistor; and
an adjustable delay circuit having first, second, and third inputs and an output, the first input of the adjustable delay circuit coupled to the input of the first driver, the output of the adjustable delay circuit coupled to the input of the second driver.

2. The apparatus of claim 1, wherein the adjustable delay circuit is configured to generate a second pulse at the output of the adjustable delay circuit based on a first pulse at the first input, the first pulse having a rising edge and a falling edge, the second pulse having a rising edge and a falling edge, the rising edge of the second pulse delayed from the rising edge of the first pulse by a first delay period and the falling edge of the second delayed from the falling edge of the first pulse by a second delay period.

3. The apparatus of claim 2, wherein the second delay period is different than the first delay period.

4. The apparatus of claim 2, wherein the apparatus has a third terminal and a fourth terminal, the third terminal coupled to the second input of the adjustable delay circuit, and the fourth terminal coupled to the third input of the adjustable delay circuit.

5. The apparatus of claim 2, wherein the adjustable delay circuit is configured to generate the rising edge of the second pulse with the first delay period based on a signal at the second input of the adjustable delay circuit and the falling edge of the second pulse with the second delay period based on a signal at the third input of the adjustable delay circuit.

6. The apparatus of claim 1, wherein the apparatus has a third terminal, the apparatus further comprises a compare circuit having a first input coupled to at least one of the first or second transistors, having a second input coupled to at least one of the third or fourth transistors, and having an output coupled to the third terminal.

7. The apparatus of claim 6, wherein the compare circuit is configured to determine which of the first or third transistors turned on or off before the other of the first or third transistors.

8. The apparatus of claim 1, wherein the apparatus has a third terminal, and the apparatus further includes a resistor coupled between the first switching terminal and the third terminal.

9. The apparatus of claim 1, wherein the apparatus has a third terminal coupled to the first input of the adjustable delay circuit.

10. The apparatus of claim 9, further comprising a frequency divider having an input coupled to the first input of the adjustable delay circuit and having an output coupled to the third terminal.

11. An apparatus, comprising:
a first transistor having a control input;
a second transistor having a control input, the second transistor coupled to the first transistor at a switching terminal;
a driver having an input, a first output coupled to the control input of the first transistor, and a second output coupled to the control input of the second transistor; and
an adjustable delay circuit having first, second, and third inputs and an output, the output of the adjustable delay circuit coupled to the input of the driver, the adjustable delay circuit configured to generate an output pulse at the output of the adjustable delay circuit based on an input pulse at the first input of the adjustable delay circuit such that:
the output pulse has a rising edge delayed from a rising edge of the input pulse by a first delay period, the first delay period based on a first voltage at the second input of the adjustable delay circuit; and
the output pulse has a falling edge delayed from a falling edge of the input pulse by a second delay period, the second delay period based on a second voltage at the third input of the adjustable delay circuit.

12. The apparatus of claim 11, wherein the second delay period is different than the first delay period.

13. The apparatus of claim 11, wherein the switching terminal is a first switching terminal and the driver is a first driver, and the apparatus further comprises:
a third transistor having a control input;
a fourth transistor having a control input, the fourth transistor coupled to the second transistor at a second switching terminal; and
a second driver having an input, a first output coupled to the control input of the third transistor, and second output coupled to the control input of the fourth transistor; and
the first input of the adjustable delay circuit is coupled to the input of the second driver.

14. The apparatus of claim 13, wherein the third and fourth transistors are larger than the first and second transistors.

15. The apparatus of claim 13, wherein the apparatus has a second terminal, and the apparatus further comprises a compare circuit having a first input coupled to at least one of the first or second transistors, having a second input coupled to at least one of the third or fourth transistors, and having an output coupled to the second terminal.

16. The apparatus of claim 15, wherein the compare circuit is configured to determine which of the first or third transistors turned on or off before the other of the first or third transistors.

17. The apparatus of claim 11, wherein the apparatus has a second terminal and a third terminal, the second terminal coupled to the second input of the adjustable delay circuit, and the third terminal coupled to the third input of the adjustable delay circuit.

18. The apparatus of claim 11, wherein the apparatus has a second terminal, and the apparatus further includes a resistor coupled between the switching terminal and the second terminal.

19. The apparatus of claim 11, wherein the apparatus has a second terminal coupled to the first input of the adjustable delay circuit.

20. An apparatus, comprising:
an adjustable delay circuit having first, second, and third inputs and an output, the adjustable delay circuit configured to generate an output pulse at the output based on an input pulse at the first input such that:
the output pulse has a rising edge delayed from a rising edge of the input pulse by a first delay period, the first delay period based on a first voltage at the second input of the adjustable delay circuit; and
the output pulse has a falling edge delayed from a falling edge of the input pulse by a second delay period, the second delay period based on a second voltage at the third input of the adjustable delay circuit.

21. The apparatus of claim 20, wherein the adjustable delay circuit comprises:
a first delay circuit having a first signal input coupled to the first input, a first voltage input coupled to the second input, and a first delay output, the first delay circuit configured to receive the input pulse at the first signal input and the first voltage at the first voltage input and generate a first delay signal at the first delay output; and
a second delay circuit having a second signal input coupled to the first input, a second voltage input coupled to the third input, and a second delay output, the second delay circuit configured to receive the input pulse at the second signal input and the second voltage at the first voltage input and generate a second delay signal at the second delay output.

22. The apparatus of claim 20, further comprising a logic circuit having a first logic circuit input, a second logic circuit input, and logic circuit output, the first logic circuit input coupled to the first delay output, the second logic circuit input coupled to the second delay output, and the logic circuit output coupled to the output of the adjustable delay circuit.
